(19) United States
(12) Patent Application Publication
(10) Pub. No.: US 2026/0068123 A1
(43) Pub. Date: Mar. 5, 2026

(54) VERTICAL FIN FIELD EFFECT TRANSISTOR AND MEMORY DEVICE

(71) Applicant: NANYA TECHNOLOGY CORPORATION, New Taipei City (TW)

(72) Inventor: Wen Kuei HUANG, New Taipei City (TW)

(21) Appl. No.: 18/823,695

(22) Filed: Sep. 4, 2024

(51) Int. Cl. H10B 12/00

(52) U.S. Cl. CPC H10B 12/315

(57) ABSTRACT

Embodiments of the present disclosure provide a memory device and a vertical fin field effect transistor. The memory device includes a memory cell including a bit line, a word line above the bit line, a plurality of semiconductor fins on the bit line and embedded in the word line, a body line physically contacting one of sidewalls of each of the semiconductor fins, and an insulating layer embedding the body line. The body line is grounded to direct the accumulated charges out of the semiconductor fins, thereby reducing the floating body effect in the memory cell.

### BACKGROUND

### Field of Invention

The present invention relates to the memory device. More particularly, the present invention relates to the memory device including the vertical fin field effect transistor.

### Description of Related Art

Surrounding gate transistor (SGT) is one of the candidates for dynamic random access memory (DRAM) design. Generally, a surrounding gate transistor includes a channel in a pillar structure and a gate surrounding the channel with source/drain regions at the top and the bottom of the pillar structure. However, the charges can be accumulated in the pillar structure, which leads to the floating body effect of the surrounding gate transistor.

### SUMMARY

According to some embodiments of the present disclosure, a vertical fin field effect transistor includes a bit line, a word line above the bit line, and a semiconductor fin on the bit line. The semiconductor fin includes a channel region surrounded by the word line, a top source/drain region on a top surface of the channel region, and a bottom source/drain region below a bottom surface of the channel region. The vertical fin field effect transistor also includes a body line physically contacting one of sidewalls of the channel region and an insulating layer embedding the body line, where the body line is grounded.

In some embodiments, the semiconductor fin and the body line are made of a same material.

In some embodiments, the semiconductor fin and the body line are integrally formed into one piece.

In some embodiments, a conductivity of the body line is higher than a conductivity of the semiconductor fin.

In some embodiments, a top surface of the body line is lower than or levelled with the top surface of the channel region.

In some embodiments, a bottom surface of the body line is levelled with the bottom surface of the channel region.

In some embodiments, the word line physically contacts others of the sidewalls of the channel region.

In some embodiments, a sidewall of the body line extends beyond another one of the sidewalls of the channel region.

In some embodiments, a sidewall of the body line is levelled with another one of the sidewalls of the channel region.

In some embodiments, the body line and the word line are separated by the insulating layer.

According to some embodiments of the present disclosure, a memory device includes a first memory cell. The first memory cell includes a first bit line, a first word line above the first bit line, a plurality of first semiconductor fins on the first bit line and embedded in the first word line, a first body line physically contacting one of sidewalls of each of the first semiconductor fins, and an insulating layer embedding the first body line.

In some embodiments, the first memory cell further includes a storage node contact covering top surfaces of the first semiconductor fins and a capacitor on the storage node contact, where bottom surfaces of the first semiconductor fins contact the first bit line.

In some embodiments, the first body line is separated from the storage node contact.

In some embodiments, the storage node contact includes a polysilicon liner contacting the top surfaces of the first semiconductor fins and a metal layer between the polysilicon liner and the capacitor.

In some embodiments, the first bit line and the first semiconductor fins extend along a first direction, and the first word line and the first body line extend along a second direction different from the first direction.

In some embodiments, the memory device further includes a second memory cell. The second memory cell includes a second bit line adjacent to the first bit line, the first word line above the second bit line, a plurality of second semiconductor fins on the second bit line and embedded in the first word line, and the first body line physically contacting one of sidewalls of each of the second semiconductor fins, where the first semiconductor fins and the second semiconductor fins are connected by the first body line.

In some embodiments, the memory device further includes a second memory cell. The second memory cell includes the first bit line, a second word line adjacent to the first word line and above the first bit line, a plurality of second semiconductor fins on the first bit line and embedded in the second word line, and a second body line physically contacting one of sidewalls of each of the second semiconductor fins.

In some embodiments, the memory device further includes a second memory cell including a plurality of second semiconductor fins on a second bit line and embedded in the first word line, a third memory cell including a plurality of third semiconductor fins on the first bit line and embedded in a second word line, and a fourth memory cell comprising a plurality of fourth semiconductor fins on the second bit line and embedded in the second word line. The first semiconductor fins and the second semiconductor fins are connected by the first body line. The third semiconductor fins and the fourth semiconductor fins are connected by a second body line. The first memory cell, the second memory cell, the third memory cell, and the fourth memory cell are arranged in a 2×2 array.

In some embodiments, the memory device further includes a word line contact connected to the first word line and a body line contact connecting the first body line and ground, where the word line contact and the body line contact are disposed on opposite sides of the first memory cell.

In some embodiments, the memory device further includes a word line contact connected to the first word line and a body line contact connecting the first body line and ground, where the word line contact and the body line contact are disposed on a same side of the first memory cell.

According to the above mentioned embodiments, a memory device includes a memory cell including a bit line, a word line, a plurality of semiconductor fins embedded in the word line, a body line physically contacting sidewalls of the semiconductor fins, and an insulating layer embedding the body line, where the body line is grounded to reduce the floating body effect in the memory cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional schematic view of a memory device, according to one embodiment of the present disclosure.

FIG. 2 illustrates an enlarged top view of the memory device in FIG. 1.

FIG. 3 illustrates a cross-sectional view of the memory device in FIG. 1.

FIG. 4 illustrates a cross-sectional view of a memory device, according to another embodiment of the present disclosure.

FIG. 5 illustrates a cross-sectional view of a memory device, according to another embodiment of the present disclosure.

FIG. 6 illustrates a cross-sectional view of a memory device, according to another embodiment of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to some embodiments of the present disclosure, a memory device includes a memory cell including a bit line, a word line, a plurality of semiconductor fins on the bit line and embedded in the word line, a body line physically contacting sidewalls of the semiconductor fins, and an insulating layer embedding the body line. The bit line, the word line, and the semiconductor fins function as vertical fin field effect transistors in the memory cell, where the body line is grounded to reduce the floating body effect of the vertical fin field effect transistors.

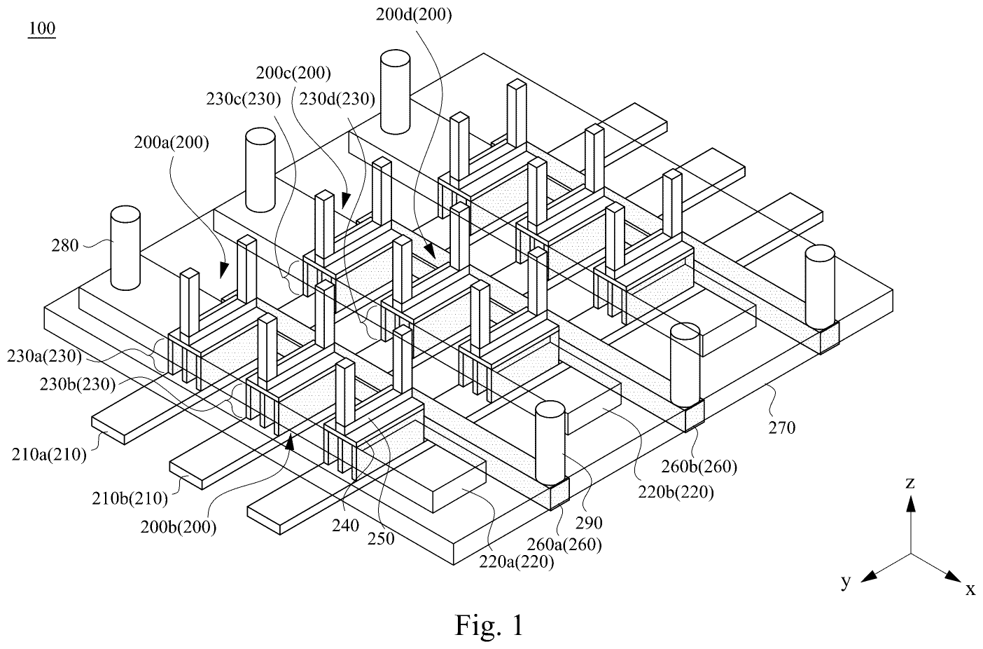

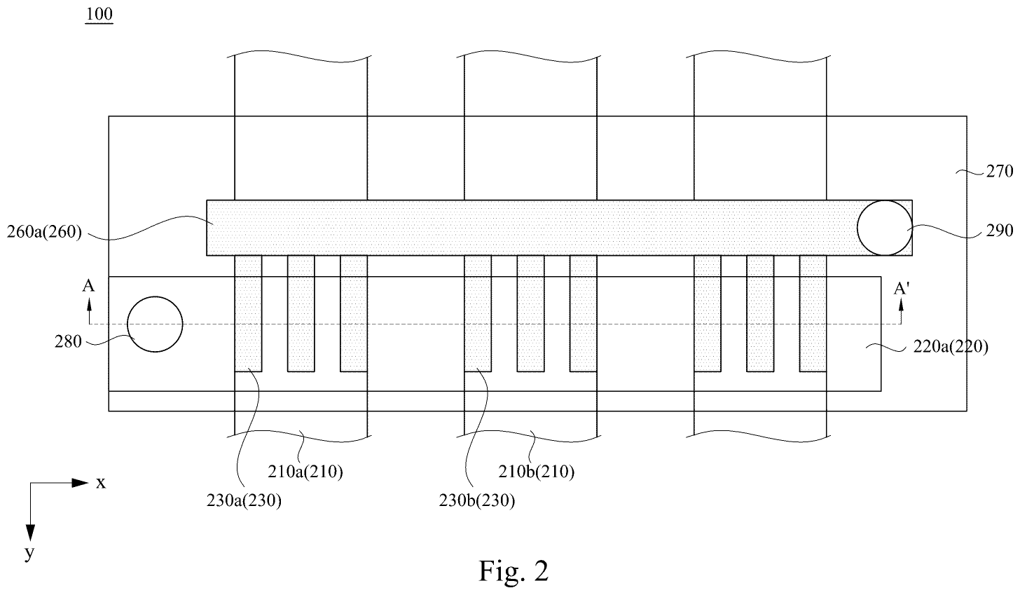

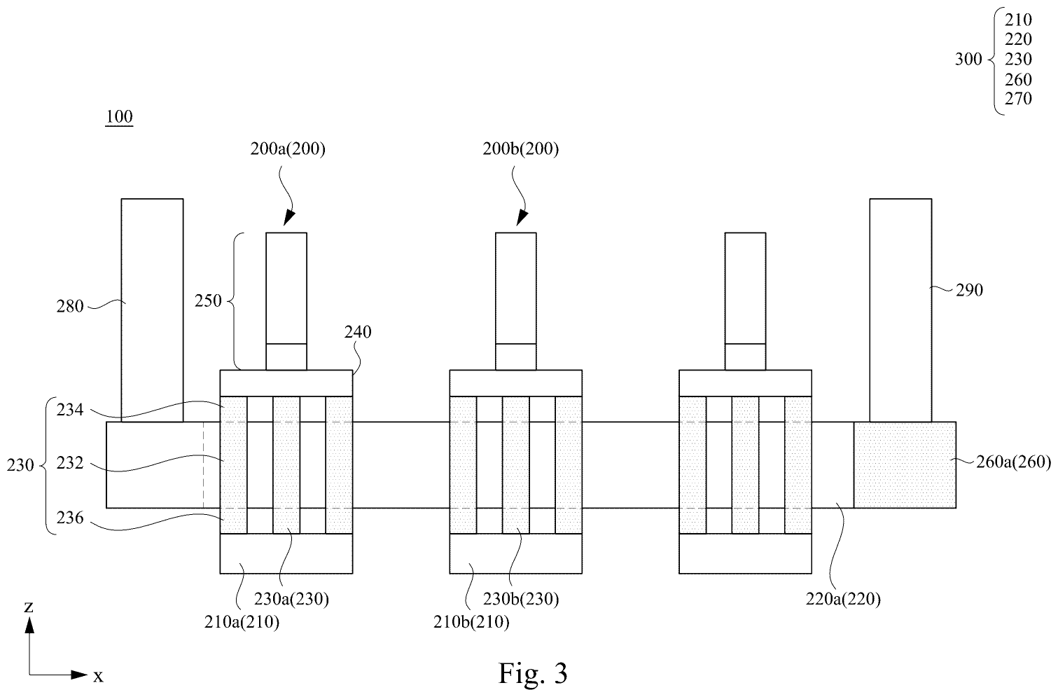

FIG. 1 illustrates a three-dimensional schematic view of a memory device 100, according to one embodiment of the present disclosure. The memory device 100 includes memory cells 200 arranged in a two-dimensional array. For the sake of simplicity, nine memory cells 200 are arranged in a 3×3 array for the memory device 100 illustrated in FIG. 1. However, no limitations on the number of memory cells 200 that may be arranged in the memory device 100 are intended. To clearly illustrate the details of the memory cells 200, FIG. 2 illustrates an enlarged top view of three memory cells 200 of the memory device 100 in FIG. 1, and FIG. 3 illustrates a cross-sectional view of the memory device 100 along the line A-A′ in FIG. 2.

Referring to FIG. 1 to FIG. 3, a memory cell 200 includes a bit line 210, a word line 220 above the bit line 210, and semiconductor fins 230 on the bit line 210. The bit line 210 extends in the y-axis direction while the word line 220 extends in the x-axis direction. The word line 220 is separated from the bit line 210 along the z-axis direction. The semiconductor fins 230 extend in the y-axis direction and are separated from each other along the x-axis direction. The semiconductor fins 230 are electrically connected to the bit line 210 and surrounded by the word line 220. For example, the bottom surfaces of the semiconductor fins 230 may contact the top surface of the bit line 210, while the sidewalls of the semiconductor fins 230 may be surrounded by the word line 220. As a result, the bit line 210, the word line 220, and the semiconductor fins 230 may function as vertical fin field effect transistors 300 in the memory cell 200.

Specifically, for each semiconductor fin 230, a middle portion of the semiconductor fin 230 is embedded in the word line 220. As the word line 220 functions as the gate of the vertical fin field effect transistors 300, the middle portion of the semiconductor fin 230 surrounded by the word line 220 may be referred as a channel region 232 of the vertical fin field effect transistor 300. In some embodiments, the word line 220 may physically contact multiple sidewalls of the channel region 232 to serve as a surrounding gate.

In addition to the channel region 232, the semiconductor fin 230 includes a top portion protruding above the word line 220 along the z-axis direction, which becomes a top source/drain region 234 on the top surface of the channel region 232. The semiconductor fin 230 also includes a bottom portion protruding below the word line 220 along the z-axis direction, which becomes a bottom source/drain region 236 below the bottom surface of the channel region 232. Therefore, a semiconductor fin 230 may function as the channel and the source/drain regions of a vertical fin field effect transistor 300.

In some embodiments, the bit line 210, the word line 220, and the semiconductor fins 230 may be made of suitable materials to form the vertical fin field effect transistors 300 in the memory cell 200. For example, the bit line 210 may include a conductive material, such as tungsten, copper, or other metal, buried in a substrate (not shown). The word line 220 may include a layer stack of oxides, polysilicon, high dielectric constant materials, metal gate materials, or combinations thereof. The semiconductor fins 230 may include silicon, polysilicon, compound semiconductor, or other semiconductor material.

The memory cell 200 further includes a storage node contact 240 and a capacitor 250 above the semiconductor fins 230 along the z-axis direction. The storage node contact 240 covers the top surfaces of the semiconductor fins 230 so that the storage node contact 240 is connected to the top source/drain regions 234 of the vertical fin field effect transistors 300. The capacitor 250 is disposed on the top surface of the storage node contact 240. To clearly illustrate the element arrangement in the memory cells 200, the storage node contact 240 and the capacitor 250 are omitted in FIG. 2.

As the semiconductor fins 230 of one memory cell 200 are sandwiched between one bit line 210 and one capacitor 250, the semiconductor fins 230 of the memory cell 200 may be referred as the channels regions 232 of the vertical fin field effect transistors 300 connected in parallel in the memory cell 200. In other words, the number of the semiconductor fins 230 sandwiched between one bit line 210 and one capacitor 250 corresponds to the number of vertical fin field effect transistors 300 in one memory cell 200. The multiple semiconductor fins 230 in the memory cell 200 may reduce the critical dimension of the vertical fin field effect transistors 300, thereby improving the unit integration in the memory device 100. Since the fin width and the fin height of the semiconductor fins 230 are related to the channel width and the channel length of the vertical fin field effect transistors 300, the thinned semiconductor fins 230 in the memory cell 200 may also increase the driving-current of the vertical fin field effect transistors 300.

In some embodiments, the storage node contact 240 may include a polysilicon liner near the semiconductor fins 230 and a metal layer between the polysilicon liner and the capacitor 250 to reduce the junction leakage between the storage node contact 240 and the semiconductor fins 230 and the contact resistance between the storage node contact 240 and the capacitor 250. For example, the storage node contact 240 may include a polysilicon liner contacting the top surfaces of the semiconductor fins 230, a metal silicide layer on the polysilicon liner, and a metal layer on the metal silicide layer.

The memory cell 200 further includes a body line 260 extending in the x-axis direction adjacent to the word line 220. The body line 260 functions as a conductive path for the vertical fin field effect transistors 300 to release excess charges in the semiconductor fins 230. Specifically, the body line 260 physically contacts one of sidewalls of each of the semiconductor fins 230, particularly the sidewall of the channel region 232 of each of the semiconductor fins 230. In other words, the semiconductor fins 230 in the memory cell 200 are connected together by the body line 260. When the charges are accumulated in the channel regions 232 during the operation of the vertical fin field effect transistors 300, the body line 260 is grounded to direct the accumulated charges out of the channel regions 232, thereby reducing the floating body effect of the vertical fin field effect transistors 300.

In some embodiments, the body line 260 and the semiconductor fins 230 may be made of a same material, such as silicon or polysilicon, to increase the charge releasing efficiency of the body line 260. The body line 260 and the semiconductor fins 230 having the same material may be formed simultaneously, which simplifies the manufacturing process of the memory cell 200. In such embodiments, the body line 260 and the semiconductor fins 230 may be integrally formed into one piece to reduce the interfaces between the body line 260 and the semiconductor fins 230, which improves the charge releasing efficiency and the structure strength.

In some other embodiments, the body line 260 and the semiconductor fins 230 may include different materials, where a conductivity of the body line 260 is higher than a conductivity of the semiconductor fins 230. The conductivity difference between the body line 260 and the semiconductor fins 230 increases the charge releasing efficiency of the body line 260. For example, the semiconductor fins 230 may be made of silicon, while the body line 260 may be made of metal.

In some embodiments, the memory cell 200 may further include an insulating layer 270 embedding the body line 260. Since the body line 260 is embedded in the insulating layer 270, the body line 260 may be referred to as “buried body line”. The body line 260 and the word line 220 may be separated by the insulating layer 270, such that the body line 260 directs the charges out of the semiconductor fins 230 rather than the word line 220. For example, a side portion of a semiconductor fin 230 may protrude from the sidewall of the word line 220 along the y-axis direction, where the body line 260 physically contacts a sidewall of the side portion of the semiconductor fin 230. Correspondingly, the other sidewalls of the side portion of the semiconductor fin 230 may physically contact the insulating layer 270. The insulating layer 270 may also interpose between the bottom surface of the word line 220 and the top surface of the bit line 210 to separate the word line 220 from the bit line 210. It should be noted that the insulating layer 270 is omitted in the cross-sectional views, such as FIG. 3 to FIG. 6, to clearly illustrate the arrangement of other elements in the memory cells 200.

In some embodiments, the bottom surface of the body line 260 may be levelled with the bottom surfaces of the channel regions 232. As shown in FIG. 3, the top surface, the bottom surface, and the sidewall of the body line 260 hidden by the word line 220 are illustrated as dashed lines in the cross-sectional view, where the bottom surface of the body line 260 is levelled with the bottom surfaces of the channel regions 232. In other words, the bottom surface of the body line 260 may be levelled with the bottom surface of the word line 220. As a result, the body line 260 is separated from the bit line 210 to direct the charges out of the semiconductor fins 230 rather than the bit line 210.

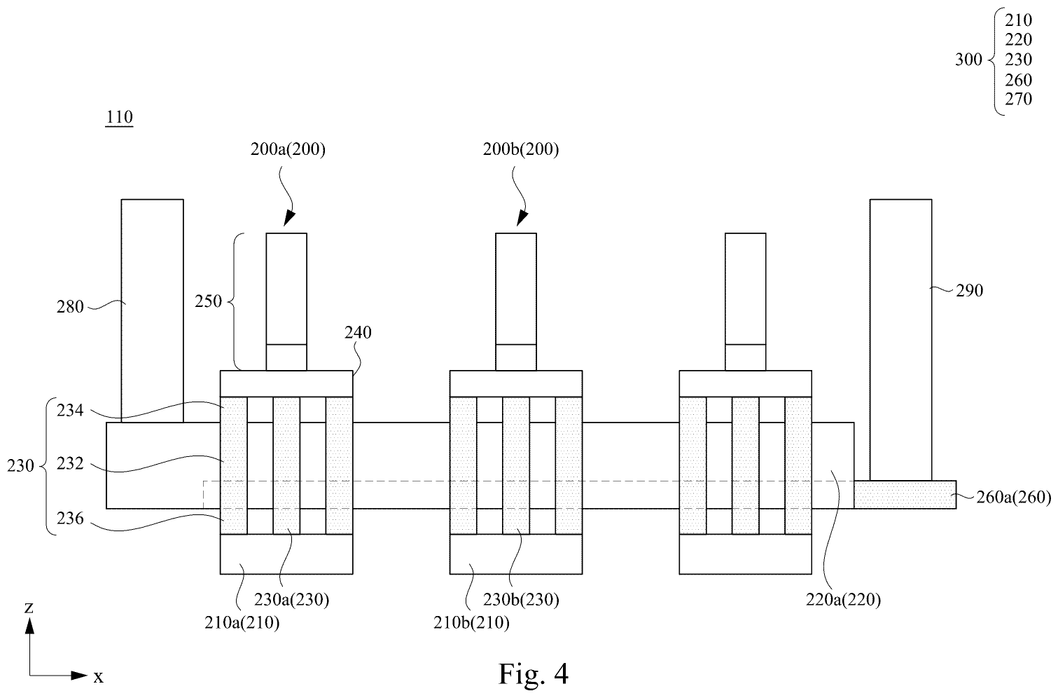

In addition, the top surface of the body line 260 may be levelled with or lower than the top surfaces of the channel regions 232. In other words, the top surface of the body line 260 may be levelled with or lower than the top surface of the word line 220. As a result, the body line 260 is separated from the storage node contact 240 to direct the charges out of the semiconductor fins 230 rather than the storage node contact 240. The memory device 100 in FIG. 3 shows the body line 260 having the top surface levelled with the top surfaces of the channel regions 232. According to another embodiment of the present disclosure, FIG. 4 illustrates a cross-sectional view of a memory device 110. The memory device 110 is similar to the memory device 100 in FIG. 3, except for the body line 260 having the top surface lower than the top surfaces of the channel regions 232.

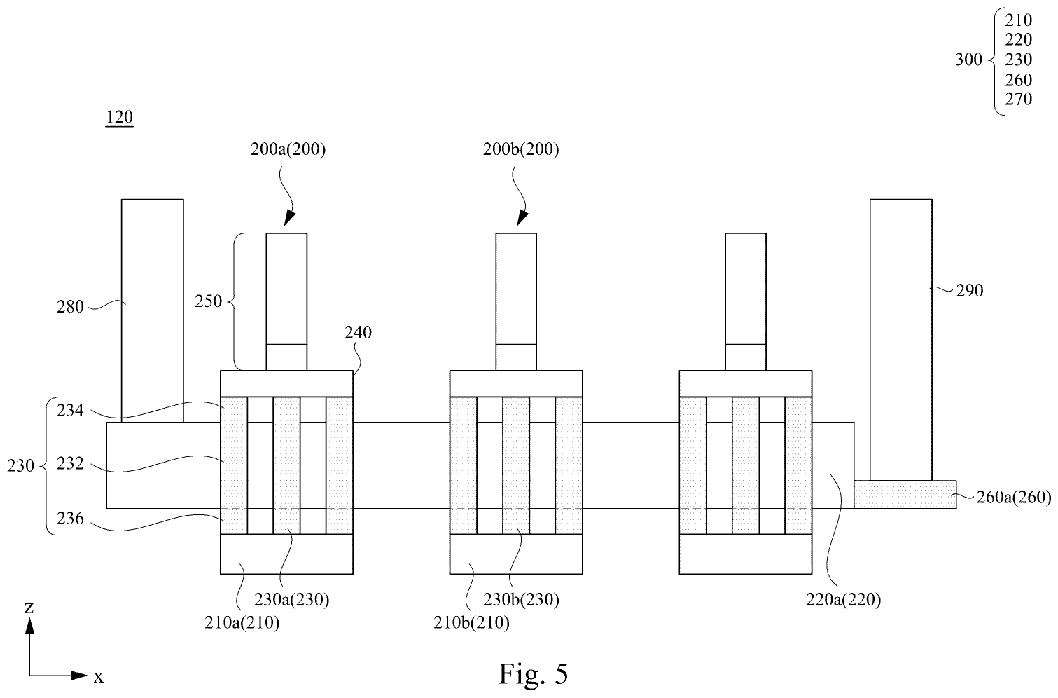

In some embodiments, a sidewall of the body line 260 may extend beyond or be levelled with a sidewall of the channel region 232 closest to the edge of the two-dimensional array of the memory cells 200. In such embodiments, each of the channel regions 232 has a sidewall fully covered by the body line 260 to increase the charge releasing efficiency of the body line 260. The memory device 110 in FIG. 4 shows the body line 260 having the sidewall extending beyond the sidewall of the channel region 232 closest to the edge of the two-dimensional array. According to another embodiment of the present disclosure, FIG. 5 illustrates a cross-sectional view of a memory device 120. The memory device 120 is similar to the memory device 110 in FIG. 4, except for the body line 260 having the sidewall levelled with the sidewall the channel region 232.

As mentioned above, a vertical fin field effect transistor 300 includes a bit line 210, a word line 220 above the bit line 210, a semiconductor fin 230 on the bit line 210 and embedded in the word line 220, a body line 260 physically contacting the semiconductor fin 230, and an insulating layer 270 embedding the body line 260. A memory cell 200 includes multiple vertical fin field effect transistors 300, where the semiconductor fins 230 of the vertical fin field effect transistors 300 are connected by the body line 260. A memory device 100 includes multiple memory cells 200, where the memory cells 200 are connected by the body line 260 or the bit line 210 to form the two-dimensional array.

For example, as shown in FIG. 1, the memory device 100 includes a first memory cell 200a, a second memory cell 200b, a third memory cell 200c, and a fourth memory cell 200d. The first memory cell 200a includes the bit line 210a, the word line 220a, the semiconductor fins 230a on the bit line 210a and embedded in the word line 220a, and the body line 260a physically contacting a sidewall of each of the semiconductor fins 230a. The second memory cell 200b includes the bit line 210b adjacent to the bit line 210a, the word line 220a, the semiconductor fins 230b on the bit line 210b and embedded in the word line 220a, and the body line 260a physically contacting a sidewall of each of the semiconductor fins 230b.

Similarly, the third memory cell 200c includes the bit line 210a, the word line 220b adjacent to the word line 220a, the semiconductor fins 230c on the bit line 210a and embedded in the word line 220b, and the body line 260b physically contacting a sidewall of each of the semiconductor fins 230c, where the word lines 220a and 220b and the body lines 260a and 260b are alternately arranged. The fourth memory cell 200d includes the bit line 210b, the word line 220b, the semiconductor fins 230d on the bit line 210b and embedded in the word line 220b, and the body line 260b physically contacting a sidewall of each of the semiconductor fins 230d.

The semiconductor fins 230a and the semiconductor fins 230b are connected by the body line 260a, the semiconductor fins 230a and the semiconductor fins 230c are connected by the bit line 210a, and the semiconductor fins 230c and the semiconductor fins 230d are connected by the body line 260b. As a result, the first memory cell 200a to the fourth memory cell 200d are arranged in a 2×2 array for the memory device 100. In some embodiments, the first memory cell 200a to the fourth memory cell 200d may be repeatedly arranged to form a 4F2 structure of a dynamic random access memory (DRAM).

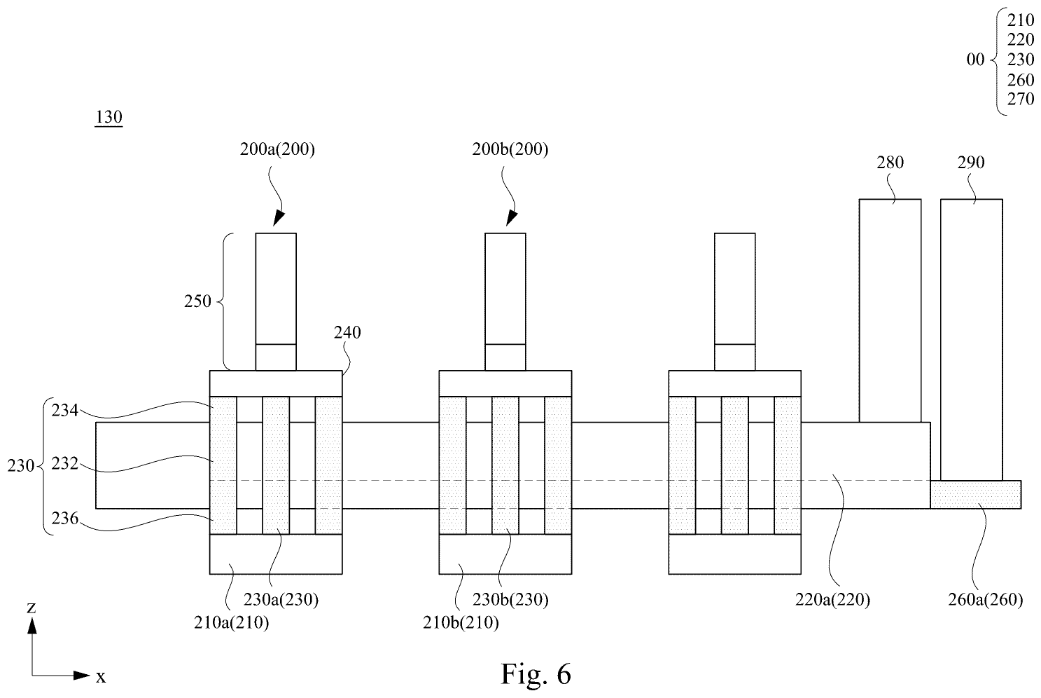

In some embodiment, the memory device 100 may further include a word line contact 280 connected to the word line 220 to apply bias onto the word line 220. The memory device 100 may also include a body line contact 290 connecting the body line 260 and ground to direct the charges out of the body line 260. The word line contact 280 and the body line contact 290 may be disposed on the opposite sides or the same side of a memory cell 200. The memory device 120 in FIG. 5 shows the word line contact 280 and the body line contact 290 on the opposite sides of the memory cell 200. According to another embodiment of the present disclosure, FIG. 6 illustrates a cross-sectional view of a memory device 130. The memory device 130 is similar to the memory device 120 in FIG. 5, except for the word line contact 280 and the body line contact 290 on the same side of the memory cell 200.

According to the above mentioned embodiments, the memory device of the present disclosure includes the memory cells, where each of the memory cells includes the bit line, the word line, the semiconductor fins on the bit line and embedded in the word line, the body line physically contacting sidewalls of the semiconductor fins, and the insulating layer embedding the body line. The bit line, the word line, and the semiconductor fins may function as vertical fin field effect transistors connected in parallel in the memory cell, thereby improving the unit integration in the memory device. The body line is grounded to direct the accumulated charges out of the semiconductor fins, which reduces the floating body effect of the vertical fin field effect transistors in the memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A vertical fin field effect transistor, comprising:
a bit line;
a word line above the bit line;
a semiconductor fin on the bit line, comprising:
a channel region surrounded by the word line;
a top source/drain region on a top surface of the channel region; and
a bottom source/drain region below a bottom surface of the channel region;
a body line physically contacting one of sidewalls of the channel region, wherein the body line is grounded; and
an insulating layer embedding the body line.

2. The vertical fin field effect transistor of claim 1, wherein the semiconductor fin and the body line are made of a same material.

3. The vertical fin field effect transistor of claim 1, wherein the semiconductor fin and the body line are integrally formed into one piece.

4. The vertical fin field effect transistor of claim 1, wherein a conductivity of the body line is higher than a conductivity of the semiconductor fin.

5. The vertical fin field effect transistor of claim 1, wherein a top surface of the body line is lower than or levelled with the top surface of the channel region.

6. The vertical fin field effect transistor of claim 1, wherein a bottom surface of the body line is levelled with the bottom surface of the channel region.

7. The vertical fin field effect transistor of claim 1, wherein the word line physically contacts others of the sidewalls of the channel region.

8. The vertical fin field effect transistor of claim 1, wherein a sidewall of the body line extends beyond another one of the sidewalls of the channel region.

9. The vertical fin field effect transistor of claim 1, wherein a sidewall of the body line is levelled with another one of the sidewalls of the channel region.

10. The vertical fin field effect transistor of claim 1, wherein the body line and the word line are separated by the insulating layer.

11. A memory device, comprising:
a first memory cell, comprising:
a first bit line;
a first word line above the first bit line;
a plurality of first semiconductor fins on the first bit line and embedded in the first word line;
a first body line physically contacting one of sidewalls of each of the first semiconductor fins; and
an insulating layer embedding the first body line.

12. The memory device of claim 11, wherein the first memory cell further comprises:
a storage node contact covering top surfaces of the first semiconductor fins, wherein bottom surfaces of the first semiconductor fins contact the first bit line; and
a capacitor on the storage node contact.

13. The memory device of claim 12, wherein the first body line is separated from the storage node contact.

14. The memory device of claim 12, wherein the storage node contact comprises:
a polysilicon liner contacting the top surfaces of the first semiconductor fins; and
a metal layer between the polysilicon liner and the capacitor.

15. The memory device of claim 11, wherein the first bit line and the first semiconductor fins extend along a first direction, and the first word line and the first body line extend along a second direction different from the first direction.

16. The memory device of claim 11, further comprising:
a second memory cell, comprising:
a second bit line adjacent to the first bit line;
the first word line above the second bit line;
a plurality of second semiconductor fins on the second bit line and embedded in the first word line; and
the first body line physically contacting one of sidewalls of each of the second semiconductor fins, wherein the first semiconductor fins and the second semiconductor fins are connected by the first body line.

17. The memory device of claim 11, further comprising:
a second memory cell, comprising:
the first bit line;
a second word line adjacent to the first word line and above the first bit line;
a plurality of second semiconductor fins on the first bit line and embedded in the second word line; and
a second body line physically contacting one of sidewalls of each of the second semiconductor fins.

18. The memory device of claim 11, further comprising:
a second memory cell comprising a plurality of second semiconductor fins on a second bit line and embedded in the first word line, wherein the first semiconductor fins and the second semiconductor fins are connected by the first body line;
a third memory cell comprising a plurality of third semiconductor fins on the first bit line and embedded in a second word line; and
a fourth memory cell comprising a plurality of fourth semiconductor fins on the second bit line and embedded in the second word line, wherein the third semiconductor fins and the fourth semiconductor fins are connected by a second body line,
wherein the first memory cell, the second memory cell, the third memory cell, and the fourth memory cell are arranged in a 2×2 array.

19. The memory device of claim 11, further comprising:
a word line contact connected to the first word line; and
a body line contact connecting the first body line and ground, wherein the word line contact and the body line contact are disposed on opposite sides of the first memory cell.

20. The memory device of claim 11, further comprising:
a word line contact connected to the first word line; and
a body line contact connecting the first body line and ground, wherein the word line contact and the body line contact are disposed on a same side of the first memory cell.
